(19) United States
(12) Patent Application Publication
(10) Pub. No.: US 2025/0014969 A1
(43) Pub. Date: Jan. 9, 2025

(54) Three-dimensional integrated system with compatible chip and manufacturing method thereof

(71) Applicant: CHINA ELECTRONICS TECHNOLOGY GROUP CORPORATION NO.44 RESEARCH INSTITUTE, Chongqing (CN)

(72) Inventors: Xiaodong WANG, Chongqing (CN); Changju LIU, Chongqing (CN)

(73) Assignee: CHINA ELECTRONICS TECHNOLOGY GROUP CORPORATION NO.44 RESEARCH INSTITUTE, Chongqing (CN)

(21) Appl. No.: 18/264,247

(22) PCT Filed: Dec. 30, 2022
(86) PCT No.: PCT/CN2022/143778

§ 371 Date: Aug. 3, 2023

(30) Foreign Application Priority Data
Sep. 27, 2022 (CN) 202211184644.1

(51) Int. Cl. H01L 23/482; H01L 23/00; H01L 23/498; H01L 25/065; H01L 27/06

(52) U.S. Cl. CPC H01L 23/4824; H01L 23/49838; H01L 24/16; H01L 25/0657; H01L 27/0688; H01L 2224/16145; H01L 2924/37001

(57) ABSTRACT

The disclosure a three-dimensional integrated system with a compatible chip and a manufacturing method thereof, which extends at least one functional chip to form an expanded chip including a functional chip and a peripheral pad. And a pad of the functional chip is electrically drawn out to the peripheral pads by rewiring. Based on an alignment bonding of the two expanded chips corresponding to the peripheral pads, or based on an alignment bonding of the functional chip and the expanded chip, an electrical connection and three-dimensional integration between two functional chips is completed simply and effectively. An integrated connection between two independent functional chips is realized based on the peripheral expanded pads. Each functional chip may be manufactured with its own independent process system.

### TECHNICAL FIELD

The disclosure relates to a technical field of semiconductors, in particular to a three-dimensional integrated system with a compatible chip and a manufacturing method thereof.

### BACKGROUND

Optoelectronic components such as optoelectronic detectors and image sensors are limited in large-scale application in airborne and aerospace fields due to their shortcomings such as complex peripheral drives and low integration. It may be said that the three-dimensional integration (3D integration) of optoelectronic electronic components or other electronic components is a development trend to achieve a high chip-level integration. In order to realize the 3D integration of different structures and different types of chips, the design of the top-level overall architecture is very critical. Whether the architecture is reasonable or not directly determines whether the 3D integration direction and route are correct or not, as well as the performance of the 3D integrated chips.

However, the current three-dimensional integration technology of multiple functional chips has at least the following shortcomings: the first is monolithic three-dimensional integration based on CMOS technology. Each functional chip is not independent, and the performance of the functional chip may not be optimal. Moreover, the types of integrated functional chips are limited, and different functional chips manufactured by different processes may not be integrated with each other. The second is to use through-silicon via (TSV) technology as a carrier to realize three-dimensional integration or three-dimensional stacking with different structures and types of chips. It is necessary to perform multiple etching and deposition of through-silicon vias based on the stacking connection among multiple chips with different functions. The manufacturing process is relatively complicated, the technical difficulty is high, and the yield rate is low.

Therefore, there is an urgent need for a three-dimensional integrated architecture technology that is compatible with a variety of different process types of chips, and has a simple manufacturing process and a high yield rate.

### SUMMARY

The disclosure provides a technical solution of a three-dimensional integrated architecture with multiple functional chips to solve the above technical problems.

The disclosure provides a three-dimensional integrated system with a compatible chip, which includes a first chip and a second chip.

The first chip is provided with a first front surface and a first back surface arranged oppositely, the first front surface includes a first area and a second area, the second area is arranged around the first area, a first functional chip is arranged on the first area, M first pads is arranged on the second area, the first functional chip is provided with N pads, the N pads of the first functional chip are electrically connected with N first pads in a one-to-one correspondence, and the K pads of the first functional chip is interconnected with the second functional chip.

The second chip is provided with a second front surface and a second back surface arranged oppositely, the second front surface includes a third area and a fourth area, the fourth area is arranged around the third area, a second functional chip is arranged on the third area, M second pads is arranged on the fourth area, the second functional chip is provided with P pads, the P pads of the second functional chip are electrically connected with the P second pads in a one-to-one correspondence, and the K pads of the second functional chip is interconnected with the first functional chip.

The first chip is aligned and bonded with the second chip through the one-to-one correspondence bonding of the M first pads and the M second pads, and the K pads of the first functional chip are electrically connected with the K pads of the second functional chip in a one-to-one correspondence.

M, N, P and K are respectively integers greater than or equal to 2, and N<M<N+P, P<M<N+P, K<N, K<P, M=N+P−K.

In some embodiments, M of the first pads are arranged around the first functional chip, M of the second pads are arranged around the second functional chip, and the M first pads on the second area are aligned with the M second pads on the fourth area one by one.

In some embodiments, M through holes are arranged on the first back surface of the first chip, and the M through holes correspond to expose the M first pads one by one.

The disclosure further provides a three-dimensional integrated system with the compatible chip, which includes a first chip and the second chip.

The first chip is provided with a first front surface and a first back surface arranged oppositely, the first front surface includes a first area, a second area and a third area, the second area is arranged around the first area, the third area is arranged around the second area, a first functional chip is arranged on the first area, p first pads is arranged on the second area, m second pads is arranged on the third area, the first functional chip is provided with n pads, the n pads of the first functional chip are electrically connected with n second pads in a one-to-one correspondence, the p first pads are electrically connected with the p second pads in a one-to-one correspondence, and the k pads of the first functional chip is interconnected with the second functional chip.

The second chip is provided with a second front surface and a second back surface arranged oppositely, p pads are electrically drawn out from the second front surface, and the k pads of the second functional chip are interconnected with the first functional chip.

The p pads of the second functional chip are connected with the p first pads in a one-to-one correspondence, so that the second functional chip is arranged on the second area of the first chip, and the k pads of the first functional chip are electrically connected with the k pads of the second functional chip in a one-to-one correspondence.

m, n, p, k are respectively integers greater than or equal to 2, and n<m<n+p, p<m<n+p, k<n, k<p, m=n+p−k.

In some embodiments, the m second pads are arranged around the first functional chip and the p first pads, and the p first pads in the second area are aligned with the p second pads of the second functional chip one by one.

In some embodiments, m through holes are arranged on the first back surface of the first chip, and the m through holes expose the m second pads one by one.

The disclosure further provides a manufacturing method of the three-dimensional integrated system with the compatible chip, which includes:
obtaining a layout design of a first functional chip and a layout design of the second functional chip;
determining a number N of pads of the first functional chip, a number P of pads of the second functional chip, and a number K of pads that need to be electrically connected between the first functional chip and the second functional chip according to the layout design of the first functional chip and the layout design of the second functional chip;
expanding the layout design of the first functional chip, arranging M first pads around a periphery of the first functional chip, and electrically connecting the N first pads with the N pads of the first functional chip in a one-to-one correspondence to obtain a layout design of a first chip;
expanding the layout design of the second functional chip, arranging M second pads around a periphery of the second functional chip, and electrically connecting the P second pads with the P pads of the second functional chip in a one-to-one correspondence to obtain a layout design of a second chip;
manufacturing the first chip with reference to the layout design of the first chip;
manufacturing the second chip with reference to the layout design of the second chip; and
aligning and bonding the first chip and the second chip through a one-to-one corresponding bonding of the M first pads and the M second pads, and electrically connecting the K pads of the first functional chip with the K pads of the second functional chip in a one-to-one correspondence.

M, N, P and K are respectively integers greater than or equal to 2, and N<M<N+P, P<M<N+P, K<N, K<P, M=N+P−K.

In some embodiments, the first chip is provided with a first front surface and a first back surface arranged oppositely, the first functional chip and M first pads are formed on the first front surface of the first chip, and the manufacturing method of a three-dimensional integrated system with a compatible chip further includes:
thinning the first back surface of the first chip;
etching the first back surface of the first chip, forming M through holes on the first back surface of the first chip, and the M through holes exposing the M first pads in a one-to-one correspondence; and
dicing, packaging and testing in sequence to obtain the three-dimensional integrated system.

The disclosure further provides a manufacturing method of the three-dimensional integrated system with the compatible chip, which includes:
obtaining a layout design of a first functional chip and a layout design of the second functional chip;
determining a number n of pads of the first functional chip, a number p of pads of the second functional chip, and a number k of pads that need to be electrically connected between the first functional chip and the second functional chip according to the layout design of the first functional chip and the layout design of the second functional chip;
expanding the layout design of the first functional chip, designing a chip connection area outside the first functional chip, arranging p first pads on the chip connection area, arranging m second pads around the first functional chip and the p first pads, providing the first functional chip with n pads, electrically connecting the n pads of the first functional chip with the n second pads in a one-to-one correspondence, and electrically connecting the p first pads with the p second pads in a one-to-one correspondence to obtain a layout design of a first chip;
manufacturing the first chip with reference to the layout design of the first chip;
manufacturing the second functional chip with reference to the layout design of the second functional chip, and electrically drawing out the p pads from a front surface of the second functional chip; and
arranging the second functional chip on the chip connection area of the first chip through a one-to-one correspondence connection between the p pads of the second functional chip and the p first pads, and electrically connecting the k pads of the first functional chip with the k pads of the second functional chip in a one-to-one correspondence; wherein
m, n, p, k are integers greater than or equal to 2, and n<m<n+p, p<m<n+p, k<n, k<p, m=n+p−k.

In some embodiments, the first chip is provided with a first front surface and a first back surface arranged oppositely, the first functional chip, p first pads and m second pads are formed on the first front surface of the first chip, and the manufacturing method of a three-dimensional integrated system with a compatible chip further includes:
thinning the first back surface of the first chip;
etching the first back surface of the first chip, forming M through holes on the first back surface of the first chip, and the M through holes exposing the M second pads in a one-to-one correspondence; and
dicing, packaging and testing in sequence to obtain the three-dimensional integrated system.

As mentioned above, the three-dimensional integrated system with the compatible chip and its manufacturing method provided by the disclosure have at least the following beneficial effects:

It extends at least one functional chip to form an expanded chip including the functional chip and the peripheral pad. And the pad of the functional chip is electrically drawn out to the peripheral pads. Based on a one-to-one alignment bonding of the two expanded chips corresponding to the peripheral pads, a bonding between the two expanded chips may be quickly and effectively realized, which completes a three-dimensional stacking integration and an electrical connection between two functional chips in the two expanded chips simply and effectively. Or based on an alignment bonding of the functional chip and the expanded chip, an integrated connection between the functional chip and the expanded chip is quickly and effectively realized, which completes a three-dimensional stacking integration and an electrical connection between the functional chip and an internal functional chip of the expanded chip simply and effectively. An integrated connection between two independent functional chips is realized based on the peripheral expanded pads. The functional chips involved in each independent chip may be independently manufactured using their own independent process system, and their types are not limited. Each functional chip may work independently to ensure the best performance. The three-dimensional integrated system has a high process compatibility for integrated functional chips. At the same time, the three-dimensional stacking integration and electrical connection among the chips are realized based on the peripheral expanded pads. Compared with a complex through-silicon-via integrated interconnection technology, this manufacturing process is relatively simple with low technical difficulty and high yield rate.

### BRIEF DESCRIPTION OF THE DRAWINGS

FIG. 1 through FIG. 3 are schematic structural views of a three-dimensional integrated system with a compatible chip according to an embodiment of the disclosure.

FIG. 4 through FIG. 6 are schematic structural views of a three-dimensional integrated system with the compatible chip according to another embodiment of the disclosure.

FIG. 7 is a schematic view of operations of a manufacturing method of the three-dimensional integrated system with the compatible chip according to an embodiment of the disclosure.

FIG. 8 through FIG. 14 are flowcharts of the manufacturing method of the three-dimensional integrated system with the compatible chip according to an embodiment of the disclosure.

FIG. 15 through FIG. 19 are flowcharts of the manufacturing method of the three-dimensional integrated system with the compatible chip according to another embodiment of the disclosure.

### DETAILED DESCRIPTION

The following describes the implementation of the disclosure through specific embodiments, and those skilled in the art can easily understand other advantages and effects of the disclosure from the content disclosed in this specification. The disclosure may also be implemented or applied through other different specific embodiments. Various details in this specification may also be modified or changed based on different viewpoints and applications without departing from the disclosure.

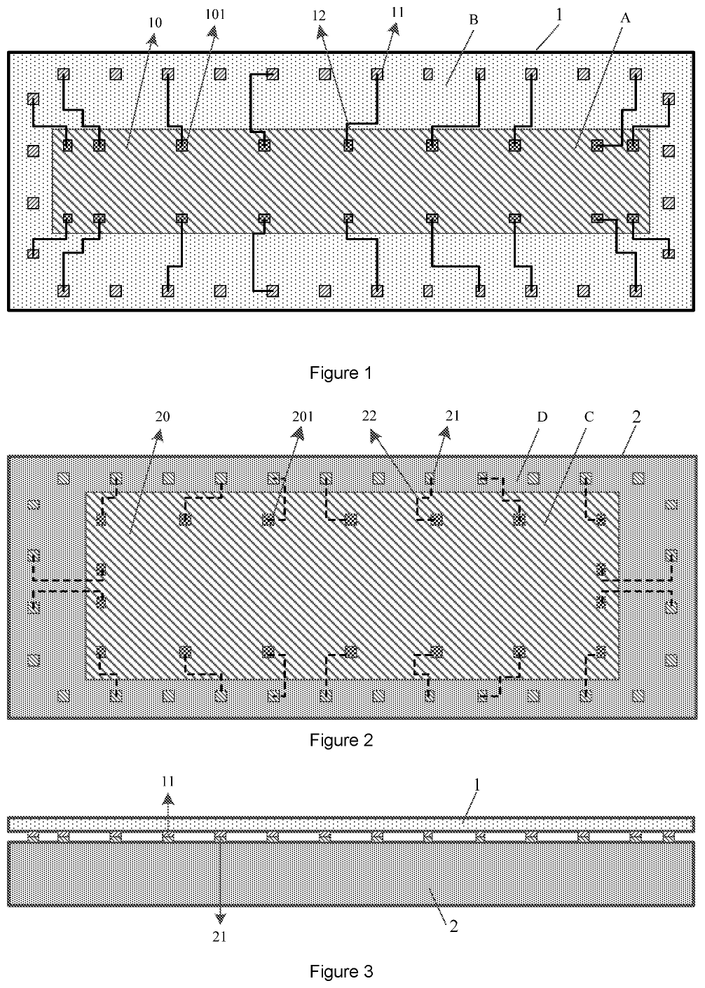

Please refer to FIG. 1 through FIG. 19. It should be noted that the illustrations provided in this embodiment are only schematically illustrating the basic idea of the disclosure. In the drawings, only the components related to the disclosure are shown rather than drawing according to the number, shape and size of the components in actual implementation. The type, quantity and ratio of each component may be changed at will during its actual implementation, and the layout of the components may also be more complicated. The structures, proportions, sizes, etc. shown in the drawings attached to this specification are only used to cooperate with the content disclosed in the specification for those who are familiar with this technology to understand and read, and are not used to limit the conditions for the implementation of the disclosure, therefore, it has no technical substantive significance, any modification of structure, change of proportional relationship or adjustment of size which should still fall within the scope covered by the technical content disclosed in the disclosure without affecting the effects and objectives that can be produced by the disclosure.

As mentioned above in the background, it is found that a current three-dimensional integration technology for multi-functional chips generally has following two technical solutions: the first is monolithic three-dimensional integration based on CMOS technology. In the monolithic three-dimensional integration, based on a unified limitation of CMOS technology, a type of integrated functional chips is limited, and can only be functional chips based on CMOS technology, and cannot be compatible with functional chips manufactured by other processes. Moreover, each functional chip is not independent of each other, and a performance of a single functional chip cannot be optimal. The second is a three-dimensional integration solution based on through-silicon via technology. Although it may realize a three-dimensional integration between multiple functional chips with different structures and different process types, it needs to implement the through-silicon via process multiple times based on a stacking connection among multiple different functional chips. The manufacturing process is relatively complicated, the technical difficulty is high, and the yield rate is low.

Based on this, the disclosure provides a three-dimensional integration technology that is compatible with different process types of chips and different functional module chips. For the two functional chips that need to be integrated, at least one functional chip is expanded. Pads are arranged on a periphery of the functional chip, and then an integrated connection of two independent chips based on expanded pads on the periphery of the functional chip is realized, so that the functional chips involved in each independent chip are not limited, which may be manufactured with independent process systems, and each functional chip may work independently to improve a process compatibility of integrated functional chips. At the same time, based on the expanded pads on the periphery of the functional chip, a three-dimensional integration and an electrical connection among the chips are realized to simplify an integration process, reduce a difficulty of process technology, and increase the yield rate.

Firstly, please refer to FIG. 1 through FIG. 3. The disclosure provides a three-dimensional integrated system with a compatible chip, which includes a first chip 1 and a second chip 2.

The first chip 1 is provided with a first front surface and a first back surface arranged oppositely, the first front surface includes a first area A and a second area B, the second area B is arranged around the first area A, a first functional chip 10 is arranged on the first area A, M first pads 11 is arranged on the second area B, the first functional chip 10 is provided with N pads 101, the N pads 101 of the first functional chip 10 is electrically connected with N first pads 11 through a wiring layer 12 in a one-to-one correspondence, and the K pads 101 of the first functional chip 10 is interconnected with the second functional chip 20.

The second chip 2 is provided with a second front surface and a second back surface arranged oppositely, the second front surface includes a third area C and a fourth area D, the fourth area D is arranged around the third area C, a second functional chip 20 is arranged on the third area C, M second pads 21 is arranged on the fourth area D, the second functional chip 20 is provided with P pads 201, the P pads 201 of the second functional chip 20 are electrically connected with the P second pads 21 through a wiring layer 22 in a one-to-one correspondence, and the K pads 201 of the second functional chip 20 is interconnected with the first functional chip 10.

Wherein, the first chip 1 is aligned and bonded with the second chip 2 through the one-to-one correspondence bonding of the M first pads 11 and the M second pads 21 and a wafer-level or die-level three-dimensional integration. And the K pads 101 (as input and output ports) of the first functional chip 10 are electrically connected with the K pads 201 (as input and output ports) of the second functional chip 20 in a one-to-one correspondence. M, N, P and K are respectively integers greater than or equal to 2, and N<M<N+P, P<M<N+P, K<N, K<P, M=N+P−K.

In detail, the first functional chip 10 shown in FIG. 1 is provided with eighteen pads 101. The second functional chip 20 shown in FIG. 2 is provided with eighteen pads 201. Thirty-two first pads 11 are arranged on the second region B shown in FIG. 1, and thirty-two second pads 21 are arranged on the second region D shown in FIG. 2. A number of pads that need to be electrically connected between the first functional chip 10 and the second functional chip 20 is four, which means that in the embodiments shown in FIG. 1 to FIG. 3, a value of M is thirty-two, a value of N is eighteen, a value of P is eighteen, and a value of K is four. It may be understood that the values of M, N, P, and K are not limited to this as long as M, N, P, and K are integers greater than or equal to 2, and N<M<N+P, P<M<N+P, K<N, K<P, M=N+P−K. The value of M is slightly smaller than N+P, and a number K of pads to be electrically connected between the first functional chip 10 and the second functional chip 20 needs to be deducted.

Specifically, please refer to FIG. 1 to FIG. 3. M of the first pads 11 are arranged around the first functional chip 10, M of the second pads 21 are arranged around the second functional chip 20, which is convenient for a scattered supporting connection when the first chip 1 is subsequently bonded and connected with the second chip 2. A size of the first chip 1 is the same as a size of the second chip 2, and the M first pads 11 on the second area B are aligned with the M second pads 21 on the fourth area D one by one, which facilitates a quick alignment when the first chip 1 is subsequently bonded and connected with the second chip 2.

In addition, the first back surface of the first chip 1 has been thinned, and M through holes (not shown in the figure) are arranged on the first back surface of the first chip 1. The M through holes correspond to expose the M first pads 11 one by one, which facilitates an electrical extraction and subsequent packaging of each functional chip in the three-dimensional integrated system. It may be understood that the M through holes may also be arranged on the second back surface of the second chip 2, and the M through holes on the second back surface of the second chip 2 correspond to expose the M second pads 21, which will not be repeated here.

Specifically, in the embodiments of FIG. 1 to FIG. 3, the first chip 1 is formed based on an expansion of the first functional chip 10, and the second chip 2 is formed based on an expansion of the second functional chip 20. Sizes and specifications of the first functional chip 10 and the second functional chip 20 are inconsistent, and distributions of the corresponding pads are quite different. At the same time, the first functional chip 10 and the second functional chip 20 are expanded to obtain the first chip 1 and the second chip 2 with exactly the same size and specification. All pads 101 of the first functional chip 10 are electrically drawn out to the first pad 11, all pads 201 of the second functional chip 20 are electrically drawn out to the second pad 21, and a number of the first pads 11 on the first chip 1 is the same as a number of the second pads 21 on the second chip 2. Distribution positions of the first pads 11 on the first chip 1 are the same as distribution positions of the second pads 21 on the second chip 2. Based on this, an alignment connection between the first chip 1 and the second chip 2 may be realized quickly, and the three-dimensional integration and electrical connection between the first functional chip 10 and the second functional chip 20 may be completed.

Wherein, the first functional chip 10 and the second functional chip 20 may be the same type of functional chip such as photodetectors arranged in series and parallel, or different types of functional chips, such as one is a photodetector and the other one is a driving control circuit. There is an electrical connection relationship between the first functional chip 10 and the second functional chip 20 to form a system-level integrated functional module, and specific chip types of the first functional chip 10 and the second functional chip 20 are not limited.

Specifically, in the embodiments of FIG. 1 to FIG. 3, the first functional chip 10 and the second functional chip 20 are respectively expanded, and a process is relatively complicated. In order to further reduce a difficulty of the process, only one of the functional chips may also be expanded.

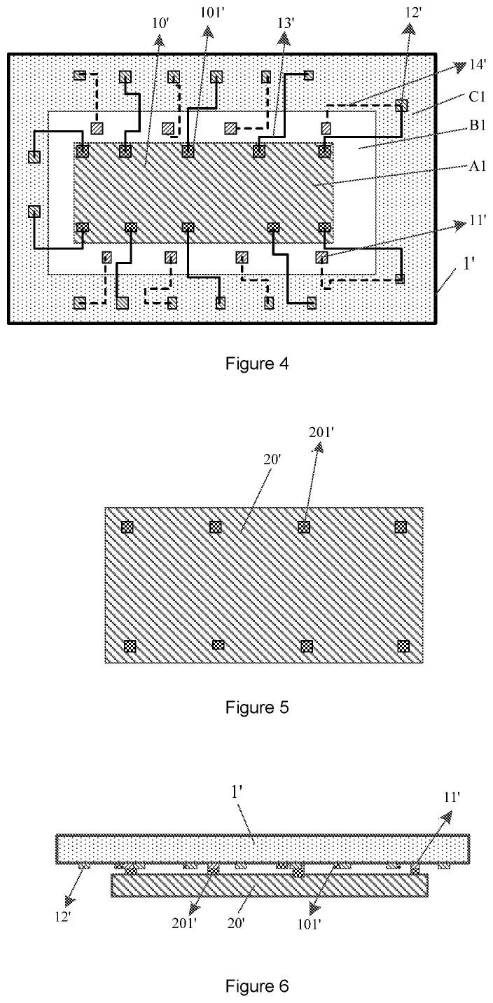

Therefore, in another optional embodiment of the disclosure, the disclosure provides a three-dimensional integrated system with a compatible chip. Please refer to FIG. 4 to FIG. 6, the three-dimensional integrated system with the compatible chip includes a first chip 1′ and a second functional chip 20′.

The first chip 1′ is provided with a first front surface and a first back surface arranged oppositely, the first front surface includes a first area A1, a second area B1 and a third area C1, the second area B1 is arranged around the first area A1, the third area C1 is arranged around the second area B1, a first functional chip 10′ is arranged on the first area A1, p first pads 11′ is arranged on the second area B1, m second pads 12′ is arranged on the third area C1, the first functional chip 10′ is provided with n pads 101′, the n pads 101′ of the first functional chip 10′ are electrically connected with n second pads 12′ through a wiring layer 13′ in a one-to-one correspondence, the p first pads 11′ are electrically connected with the p second pads 12′ through a wiring layer 14′ in a one-to-one correspondence, and the k pads 101′ of the first functional chip 10′ is interconnected with the second functional chip 20′. A second functional chip 20′is provided with a second front surface and a second back surface arranged oppositely, p pads 201′ are electrically drawn out from the second front surface, and the k pads 201′ of the second functional chip 20′ are interconnected with the first functional chip 10′.

Wherein, the p pads 201′ of the second functional chip 20′ are connected with the p first pads 11′ in a one-to-one correspondence, so that the second functional chip 20′ is arranged on the second area B1 of the first chip 10′, and the k pads 101′ of the first functional chip 10′ are electrically connected with the k pads 201′ of the second functional chip 20′ in a one-to-one correspondence. m, n, p, k are respectively integers greater than or equal to 2, and n<m<n+p, p<m<n+p, k<n, k<p, m=n+p−k.

In detail, the first functional chip 10′ shown in FIG. 4 is provided with 10 pads 101′, and the second functional chip 20′ shown in FIG. 5 is provided with 8 pads 201′. The second area B1 shown in FIG. 4 is provided with 8 first pads 11′, and the third area C1 shown in FIG. 4 is provided with 16 second pads 12′. A number of pads that need to be electrically connected between the first functional chip 10′ and the second functional chip 20′ is 2, which means that in an embodiment shown in FIG. 4 to FIG. 6, a value of m is 16, a value of n is 10, a value of p is 8, and a value of k is 2. It may be understood that the values of m, n, p, and k are not limited to this as long as m, n, p, and k are integers greater than or equal to 2, and n<m<n+p, p<m<n+p, k<n, k<p, m=n+p−k. The value of m is slightly smaller than n+p, and a number k of pads to be electrically connected between the first functional chip 10′ and the second functional chip 20′ needs to be deducted.

Specifically, please refer to FIG. 4 to FIG. 6. m second pads 12′ are arranged around the first functional chip 10′ and p first pads 11′, which is convenient for the pads of the first functional chip 10′ and the pads of the second functional chip 20′ to electrically drawn out. A size of the second functional chip 20′ is the same as a size of the second area B1, and the p first pads 11′ on the second area B1 are aligned with the p second pads 12′ of the second functional chip 20′ one by one, which facilitates a quick alignment when the first chip 1′ is subsequently integrated and connected with the second functional chip 20′.

In addition, the first back surface of the first chip 1′ has been thinned, m through holes (not shown in the figure) are arranged on the first back surface of the first chip 1′, and the m through holes correspond to expose m second pads 12′, which facilitates an electrical extraction and subsequent packaging of each functional chip in the three-dimensional integrated system.

It may be understood that, similar to the above embodiment, it is also possible to integrate more functional chips on the expanded first chip 1′, and only need to reserve functional chip mounting areas and corresponding electrical connection pads on the first chip 1′. For details, please refer to the above-mentioned embodiments, which will not be repeated here.

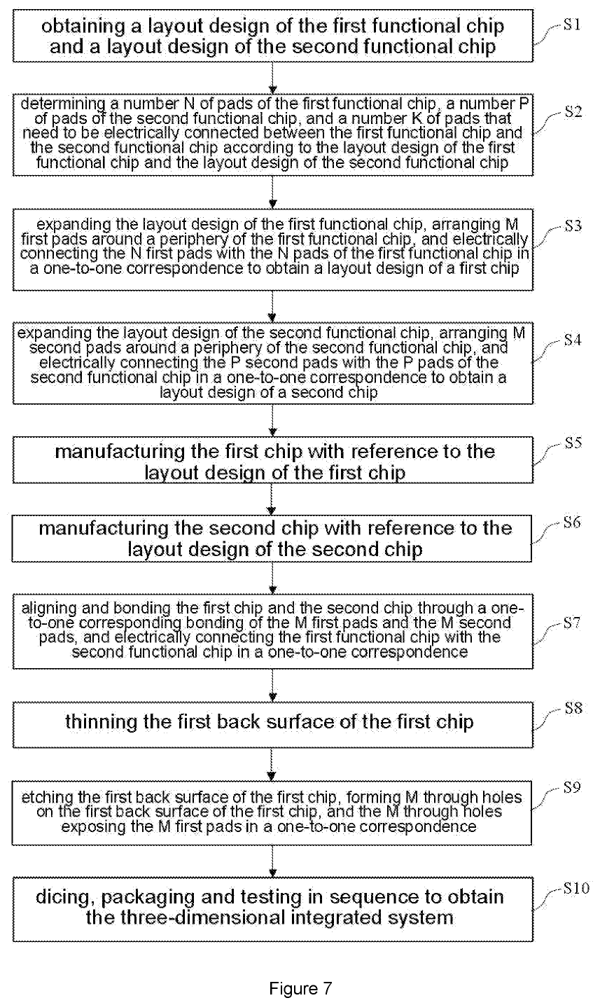

Secondly, corresponding to the embodiment shown in FIG. 1 to FIG. 3, the disclosure provides a manufacturing method of the three-dimensional integrated system with the compatible chip. Please refer to FIG. 7, the manufacturing method of the three-dimensional integrated system with the compatible chip includes:

S1: obtaining a layout design of the first functional chip and a layout design of the second functional chip;
S2: determining a number N of pads of the first functional chip, a number P of pads of the second functional chip, and a number K of pads that need to be electrically connected between the first functional chip and the second functional chip according to the layout design of the first functional chip and the layout design of the second functional chip;
S3: expanding the layout design of the first functional chip, arranging M first pads around a periphery of the first functional chip, and electrically connecting the N first pads with the N pads of the first functional chip in a one-to-one correspondence to obtain a layout design of a first chip;
S4: expanding the layout design of the second functional chip, arranging M second pads around a periphery of the second functional chip, and electrically connecting the P second pads with the P pads of the second functional chip in a one-to-one correspondence to obtain a layout design of a second chip;
S5: manufacturing the first chip with reference to the layout design of the first chip;
S6: manufacturing the second chip with reference to the layout design of the second chip; and
S7: aligning and bonding the first chip and the second chip through a one-to-one corresponding bonding of the M first pads and the M second pads and a wafer-level or die-level 3D integration bonding, and electrically connecting the K pads of the first functional chip with the K pads of the second functional chip in a one-to-one correspondence.

Wherein, M, N, P and K are respectively integers greater than or equal to 2, and N<M<N+P, P<M<N+P, K<N, K<P, M=N+P−K.

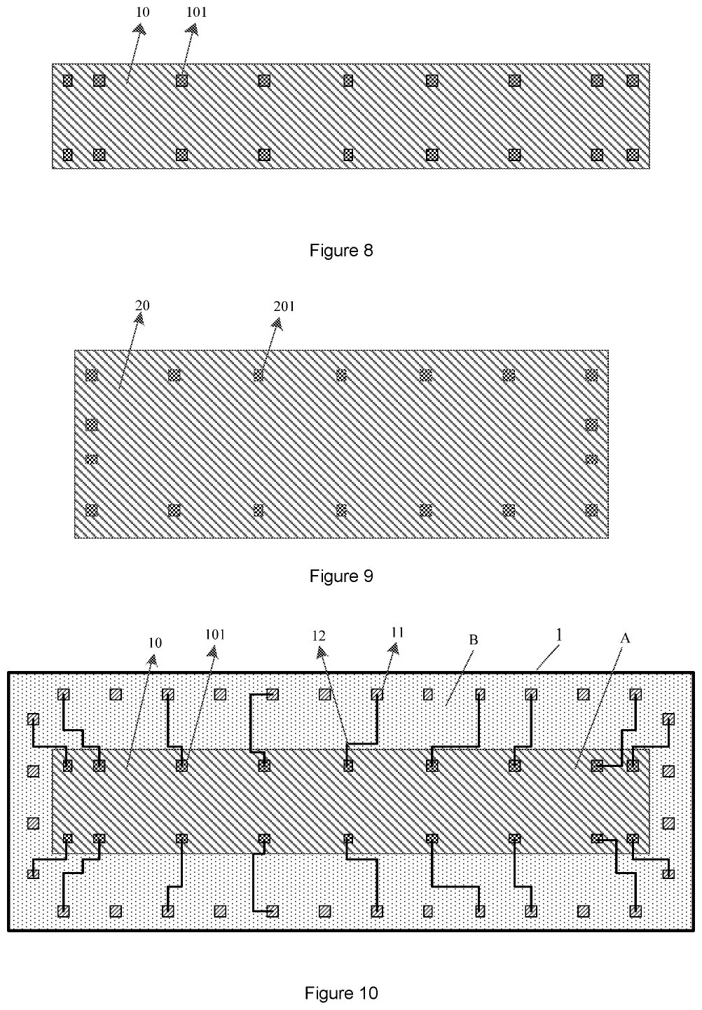

In detail, in S1, in an optional embodiment of the disclosure, obtaining the layout design of the first functional chip 10 is shown in FIG. 8. Please refer to FIG. 8. The first functional chip 10 is provided with 18 pads 101, and the obtained layout design of the second functional chip 20 is shown in FIG. 9. Please refer to FIG. 9. The second functional chip 20 is provided with 18 pads 201.

Wherein, the values of M and N are not limited to this as long as M and N are integers greater than or equal to 2 respectively, the values of M and N may be the same or different. Moreover, the sizes and specifications of the first functional chip 10 and the second functional chip 20 are inconsistent, the distributions of the corresponding pads are quite different, the number of pads and the distribution positions of the pads are different, and the first functional chip 10 and the second functional chip 20 may not be directly aligned and electrically connected.

Specifically, in S2, the number N of pads of the first functional chip, a number P of pads of the second functional chip, and a number K of pads that need to be electrically connected between the first functional chip and the second functional chip are determined according to the layout design of the first functional chip and the layout design of the second functional chip. The number M of the first pads arranged on a periphery of the first functional chip or the number M of the second pads arranged on a periphery of the second functional chip are determined according to the above three parameters when the layout design is expanded. M=N+P−K, the value of M is slightly smaller than N+P, and the number K of pads to be electrically connected between the first functional chip and the second functional chip needs to be deducted.

Specifically, in S3 to S4, the layout of the first functional chip and the layout design of the second functional chip are expanded respectively based on the layout design of the first functional chip, the layout design of the second functional chip, the number M of the first pads and the number M of the second pads obtained in S2. M first pads are arranged around the periphery of the first functional chip, and M second pads are arranged around the periphery of the second functional chip, and the M first pads and the M second pads are aligned one by one. At the same time, through a redesigned wiring layer, the N first pads are electrically connected with the N pads of the first functional chip in a one-to-one correspondence, and the P second pads are electrically connected with the P pads of the second functional chip in a one-to-one correspondence to obtain layout designs of the first chip and the second chip.

In more detail, in S3 to S4, in order to further facilitate a subsequent alignment of the first chip and the second chip when bonding, the size of the first chip obtained based on the expansion of the first functional chip is the same as the size of the second chip expanded based on the second functional chip.

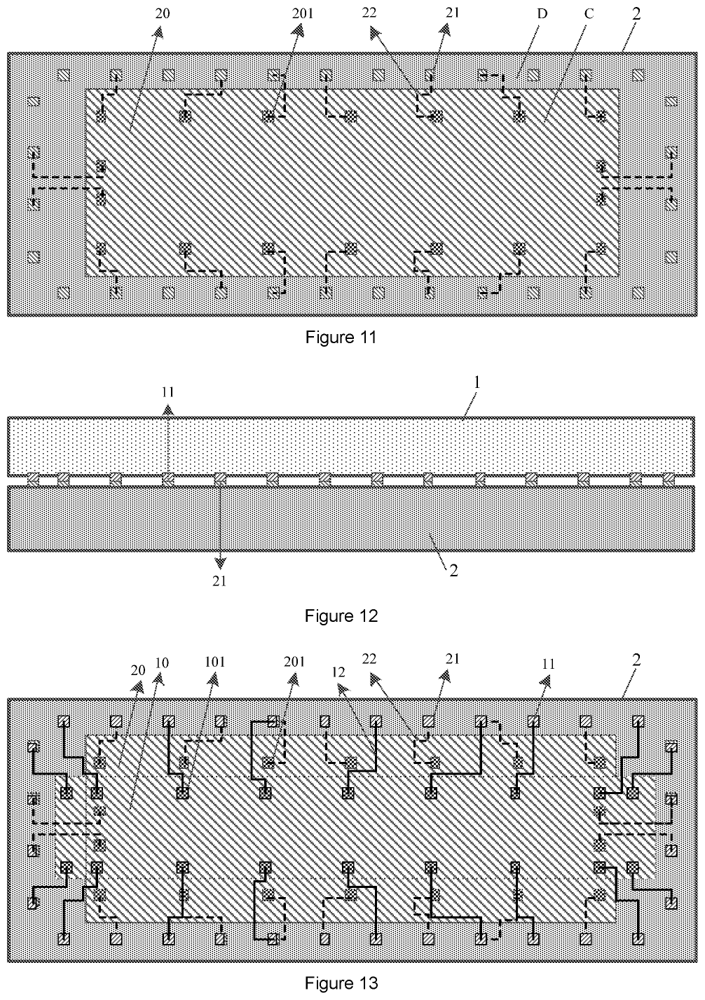

In an optional embodiment of the disclosure, the layout of the first functional chip 10 shown in FIG. 8 is expanded to obtain the layout design of the first chip 1 as shown in FIG. 10. The layout of the second functional chip 20 shown in FIG. 9 is expanded to obtain the layout design of the second chip 2 as shown in FIG. 11. Please refer to FIG. 10 to FIG. 11, the size of the first chip 1 is the same as the size of the second chip 2.

Specifically, in S5 to S6, referring to the layout design of the first chip and the layout design of the second chip, an independent manufacturing is carried out to obtain the first chip and the second chip. Wherein, the first functional chip inside the first chip and the second functional chip inside the second chip may be manufactured based on different processes, and can be compatible with functional chips manufactured by different processes.

In an optional embodiment of the disclosure, the first chip 1 manufactured with reference to the layout design of the first chip 1 is shown in FIG. 10, and the second chip 2 obtained with reference to the layout design of the second chip 2 is shown in FIG. 11.

Specifically, in S7, through a wafer-level hybrid bonding or die-level bump bonding, etc., the M first pads are bonded with M second pads in a one-to-one correspondence, so that the first chip is aligned and bonded with the second chip. And the K pads of the first functional chip are electrically connected with the K pads of the second functional chip in a one-to-one correspondence, so that a three-dimensional integration of the first chip and the second chip is completed.

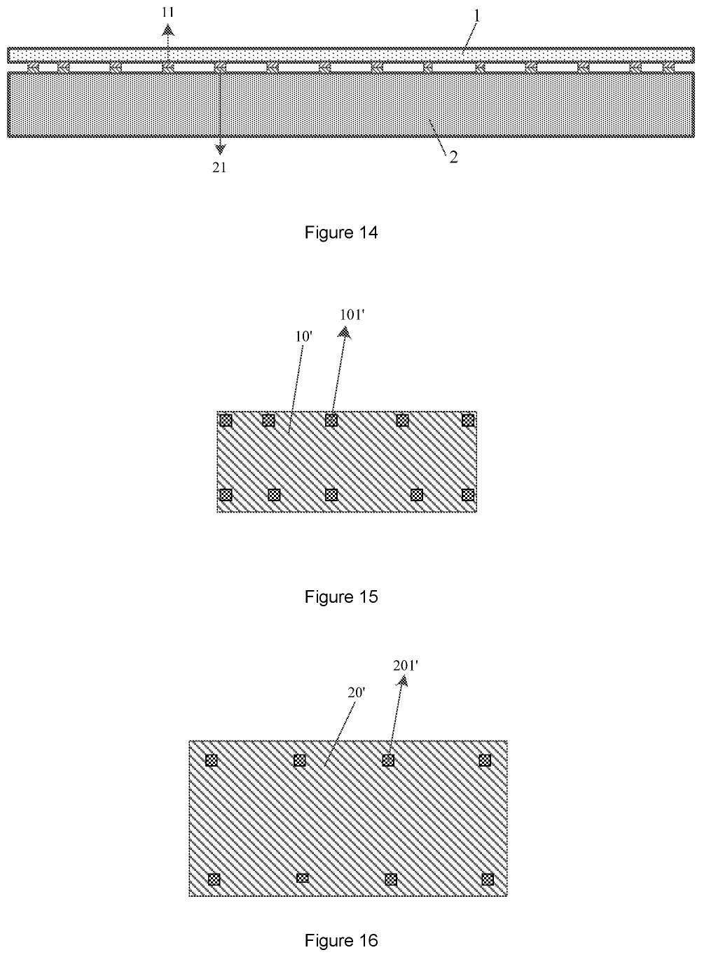

In an optional embodiment of the disclosure, the first chip 1 shown in FIG. 10 and the second chip 2 shown in FIG. 11 are bonded and integrated to obtain structures shown in FIG. 12 and FIG. 13. Wherein, FIG. 12 is a side view, and FIG. 13 is a partial perspective view of a bonding interface.

In some embodiments, the first chip is provided with the first front surface and the first back surface arranged oppositely. The first functional chip and the first pad are formed on the first front surface of the first chip, which means that a functional structure on the first chip is arranged on the first front surface. Please refer to FIG. 7, the manufacturing method of the three-dimensional integrated system with the compatible chip further includes:
S8: please refer to FIG. 14, thinning the first back surface of the first chip 1 through planarizing the first back surface;
S9: etching the first back surface of the first chip 1, forming M through holes on the first back surface of the first chip 1, and the M through holes exposing the M first pads in a one-to-one correspondence to facilitate a package bonding of the first chip 1 and the second chip 2; and
S10: dicing, packaging and testing in sequence to obtain the three-dimensional integrated system, which may refer to the conventional art and will not be repeated here.

It may be understood that, in S9, M through holes may also be arranged on the second back surface of the second chip, and the M through holes on the second back surface of the second chip expose M second pads correspondingly.

It should be noted that, in the above method embodiment, the first functional chip and the second functional chip are respectively expanded, and the process is relatively complicated. In order to further reduce the difficulty of process, it is also possible to expand only one of the functional chips.

Therefore, in another optional embodiment of the disclosure, corresponding to the embodiments shown in FIG. 4 to FIG. 6, a manufacturing method for the three-dimensional integrated system with the compatible chips is further provided, which includes:
Stp1: obtaining a layout design of a first functional chip and a layout design of the second functional chip;
Stp2: determining a number n of pads of the first functional chip, a number p of pads of the second functional chip, and a number k of pads that need to be electrically connected between the first functional chip and the second functional chip according to the layout design of the first functional chip and the layout design of the second functional chip;
Stp3: expanding the layout design of the first functional chip, designing a chip connection area outside the first functional chip, arranging p first pads on the chip connection area, arranging m second pads around the first functional chip and the p first pads, providing the first functional chip with n pads, electrically connecting the n pads of the first functional chip with the n second pads in a one-to-one correspondence, and electrically connecting the p first pads with the p second pads in a one-to-one correspondence to obtain a layout design of a first chip;
Stp4: manufacturing the first chip with reference to the layout design of the first chip;
Stp5: manufacturing the second functional chip with reference to the layout design of the second functional chip, and electrically drawing out the p pads from a front surface of the second functional chip; and
Stp6: arranging the second functional chip on the chip connection area of the first chip through a one-to-one correspondence connection between the p pads of the second functional chip and the p first pads, and electrically connecting the k pads of the first functional chip with the k pads of the second functional chip in a one-to-one correspondence; wherein, m, n, p, k are integers greater than or equal to 2, and n<m<n+p, p<m<n+p, k<n, k<p, m=n+p−k.

Specifically, in Stp2, a number n of pads of the first functional chip, a number p of pads of the second functional chip, and a number k of pads that need to be electrically connected between the first functional chip and the second functional chip are determined according to the layout design of the first functional chip and the layout design of the second functional chip. The number m of the first pads arranged on a periphery of the first functional chip or the number M of the second pads arranged on a periphery of the second functional chip are determined according to the above three parameters when the layout design is expanded. m=n+p−k, the value of m is slightly smaller than n+p, and the number k of pads to be electrically connected between the first functional chip and the second functional chip needs to be deducted.

In an optional embodiment of the disclosure, the obtained layout design of the first functional chip 10′ is shown in FIG. 15. Please refer to FIG. 15, the first functional chip 10′ is provided with ten pads 101′. The obtained layout design of the second functional chip 20′ is shown in FIG. 16. Please refer to FIG. 16, the second functional chip 20′ is provided with eight pads 101′. The number of pads required for an electrical connection between the first functional chip 10′ and the second functional chip 20′ is two.

Specifically, in Stp3, the layout design of the first functional chip is expanded based on the layout design of the first functional chip, the number m of the first pads obtained in Stp2 and the number p of pads of the second functional chip. The chip connection area is designed outside the first functional chip and p first pads are arranged on the chip connection area. The connection area is used to arrange and connect an independent second function chip, providing m second pad around the first functional chip and the p first pads. The first functional chip is provided with n pads, the n pads of the first functional chip are electrically connected with the n second pads in a one-to-one correspondence through an internal wiring layer, and the p first pads are electrically connected with the p second pads in a one-to-one correspondence to complete a layout design of a first chip.

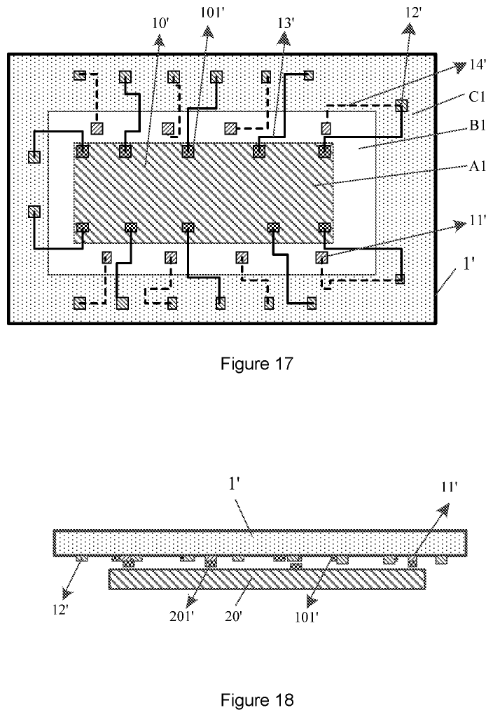

In an optional embodiment of the disclosure, the layout design of the first functional chip 10′ as shown in FIG. 15 is expanded to obtain the layout design of the first chip 1′ as shown in FIG. 17.

Specifically, in Stp4 to Stp5, referring to the layout design of the first chip and the layout design of the second function chip, an independent manufacturing is carried out to obtain the first chip and the second functional chip. Wherein, the first functional chip and the second functional chip inside the first chip may be manufactured based on different processes, and are compatible with functional chips manufactured by different processes.

In an optional embodiment of the disclosure, the first chip 1′ manufactured with reference to the layout design of the first chip 1′ is shown in FIG. 17. The second functional chip 20′ manufactured with reference to the layout design of the second functional chip 20′ is shown in FIG. 16.

Specifically, in Stp6, using methods such as wafer-level thermocompression bonding, the p pads of the second functional chip are connected with the p first pads in a one-to-one correspondence, so that the second functional chip is arranged on the chip connection area of the first chip. And the k pads of the first functional chip are electrically connected with the k pads of the second functional chip in a one-to-one correspondence, which completes the three-dimensional integration of the first chip and the second functional chip.

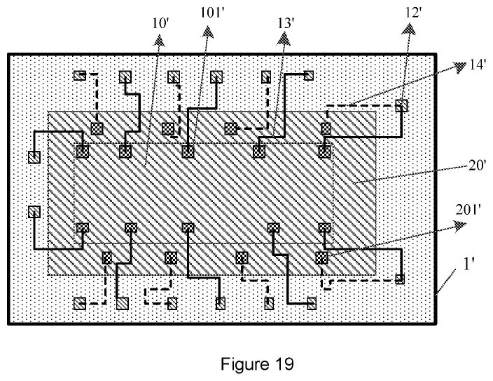

In an optional embodiment of the disclosure, the first functional chip 20′ as shown in FIG. 16 and the first chip 1′ as shown in FIG. 17 are connected and integrated to obtain the structures as shown in FIG. 18 to FIG. 19. Wherein, FIG. 18 is a side view, and FIG. 19 is a partial perspective view of a bonding interface.

In some embodiments, the first chip is provided with a first front surface and a first back surface arranged oppositely, the first functional chip, p first pads and m second pads are formed on the first front surface of the first chip, and the manufacturing method of a three-dimensional integrated system with the compatible chip further includes:
Stp7: thinning the first back surface of the first chip through planarizing the first back surface;
Stp8: etching the first back surface of the first chip, forming m through holes on the first back surface of the first chip, and the m through holes exposing the m second pads in a one-to-one correspondence to facilitate a subsequent package bonding; and
Stp9: dicing, packaging and testing in sequence to obtain the three-dimensional integrated system, which may refer to the conventional art and will not be repeated here.

It should be noted that many operations of the conventional process are omitted in the above embodiments, which are well known to those skilled in the art and will not be repeated here. Meanwhile, the above-mentioned embodiment only introduces the system-level three-dimensional integration of two functional chips, and the system-level three-dimensional integration of three or more functional chips may be similar to this, which will not be repeated here.

In summary, in the three-dimensional integrated system with the compatible chip and its manufacturing method provided by the disclosure, it extends at least one functional chip to form the expanded chip including the functional chip and the peripheral pad. And the pad of the functional chip is electrically drawn out to the peripheral pads. Based on the one-to-one alignment bonding of the two expanded chips corresponding to the peripheral pads, the bonding and integration between the two expanded chips may be quickly and effectively realized, which completes the three-dimensional stacking integration and the electrical connection between two functional chips in the two expanded chips simply and effectively. Or based on an alignment bonding of the functional chip and the expanded chip, the integrated connection between the functional chip and the expanded chip is quickly and effectively realized, which completes the three-dimensional stacking integration and an electrical connection between the functional chip and the internal functional chip of the expanded chip simply and effectively. The integrated connection between two independent functional chips is realized based on the peripheral expanded pads. The functional chips involved in each independent chip may be independently manufactured using their own independent process system, and their types are not limited. Each functional chip may work independently to ensure the best performance. The three-dimensional integrated system has a high process compatibility for integrated functional chips. At the same time, the three-dimensional stacking integration and electrical connection among the chips are realized based on the peripheral expanded pads. Compared with a complex through-silicon-via integrated interconnection technology, this manufacturing process is relatively simple with low technical difficulty and high yield rate.

The above-mentioned embodiments merely illustrate the principles and effects of the disclosure, but are not intended to limit the disclosure. Anyone skilled in the art may modify or change the above embodiments without departing from the range of the disclosure. Therefore, all equivalent modifications or changes made by those with ordinary knowledge in the technical field without departing from the range and technic disclosed in the disclosure should still be covered by the claims of the disclosure.

What is claimed is:

1. A three-dimensional integrated system with a compatible chip, comprising:
a first chip, provided with a first front surface and a first back surface arranged oppositely, the first front surface comprising a first area and a second area, the second area being arranged around the first area, a first functional chip being arranged on the first area, M first pads being arranged on the second area, the first functional chip being provided with N pads, the N pads of the first functional chip being electrically connected with N of the first pads in a one-to-one correspondence, and the K pads of the first functional chip being interconnected with a second functional chip; and
a second chip, provided with a second front surface and a second back surface arranged oppositely, the second front surface comprising a third area and a fourth area, the fourth area being arranged around the third area, the second functional chip being arranged on the third area, M second pads being arranged on the fourth area, the second functional chip being provided with P pads, the P pads of the second functional chip being electrically connected with the P of the second pads in a one-to-one correspondence, and the K pads of the second functional chip being interconnected with the first functional chip; wherein
the first chip is aligned and bonded with the second chip through the one-to-one correspondence bonding of the M first pads and the M second pads, and the K pads of the first functional chip are electrically connected with the K pads of the second functional chip in a one-to-one correspondence;
M, N, P and K are respectively integers greater than or equal to 2, and N<M<N+P, P<M<N+P, K<N, K<P, M=N+P−K.

2. The three-dimensional integrated system with the compatible chip according to claim 1, wherein
the M first pads are arranged around the first functional chip, the M second pads are arranged around the second functional chip, and the M first pads on the second area are aligned with the M second pads on the fourth area one by one.

3. The three-dimensional integrated system with the compatible chip according to claim 1, wherein
M through holes are arranged on the first back surface of the first chip, and the M through holes correspond to expose the M first pads one by one.

4. A three-dimensional integrated system with the compatible chip, comprising:
a first chip, provided with a first front surface and a first back surface arranged oppositely, the first front surface comprising a first area, a second area and a third area, the second area being arranged around the first area, the third area being arranged around the second area, a first functional chip being arranged on the first area, p first pads being arranged on the second area, m second pads being arranged on the third area, the first functional chip being provided with n pads, the n pads of the first functional chip being electrically connected with n of the second pads in a one-to-one correspondence, the p first pads being electrically connected with p of the second pads in a one-to-one correspondence, and k pads of the first functional chip being interconnected with a second functional chip; and
the second functional chip, provided with a second front surface and a second back surface arranged oppositely, p pads being electrically drawn out from the second front surface, and k pads of the second functional chip being interconnected with the first functional chip; wherein
the p pads of the second functional chip are connected with the p first pads in a one-to-one correspondence, so that the second functional chip is arranged on the second area of the first chip, and the k pads of the first functional chip are electrically connected with the k pads of the second functional chip in a one-to-one correspondence;
m, n, p, k are respectively integers greater than or equal to 2, and n<m<n+p, p<m<n+p, k<n, k<p, m=n+p−k.

5. The three-dimensional integrated system with the compatible chip according to claim 4, wherein
the m second pads are arranged around the first functional chip and the p first pads, and the p first pads in the second area are aligned with the p second pads of the second functional chip one by one.

6. The three-dimensional integrated system with the compatible chip according to claim 4, wherein
m through holes are arranged on the first back surface of the first chip, and the m through holes expose the m second pads one by one.

7. A manufacturing method of a three-dimensional integrated system with a compatible chip, comprising:
obtaining a layout design of a first functional chip and a layout design of the second functional chip;
determining a number N of pads of the first functional chip, a number P of pads of the second functional chip, and a number K of pads that need to be electrically connected between the first functional chip and the second functional chip according to the layout design of the first functional chip and the layout design of the second functional chip;
expanding the layout design of the first functional chip, arranging M first pads around a periphery of the first functional chip, and electrically connecting N of the first pads with the N pads of the first functional chip in a one-to-one correspondence to obtain a layout design of a first chip;
expanding the layout design of the second functional chip, arranging M second pads around a periphery of the second functional chip, and electrically connecting P of the second pads with the P pads of the second functional chip in a one-to-one correspondence to obtain a layout design of a second chip;
manufacturing the first chip with reference to the layout design of the first chip;
manufacturing the second chip with reference to the layout design of the second chip; and
aligning and bonding the first chip and the second chip through a one-to-one corresponding bonding of the M first pads and the M second pads, and electrically connecting the K pads of the first functional chip with the K pads of the second functional chip in a one-to-one correspondence; wherein
M, N, P and K are respectively integers greater than or equal to 2, and N<M<N+P, P<M<N+P, K<N, K<P, M=N+P−K.

8. The manufacturing method of the three-dimensional integrated system with the compatible chip according to claim 7, wherein
the first chip is provided with a first front surface and a first back surface arranged oppositely, the first functional chip and the M first pads are formed on the first front surface of the first chip, and the manufacturing method further comprises:
thinning the first back surface of the first chip;
etching the first back surface of the first chip, forming M through holes on the first back surface of the first chip, and the M through holes exposing the M first pads in a one-to-one correspondence; and
dicing, packaging and testing in sequence to obtain the three-dimensional integrated system.

9. A method of manufacturing the three-dimensional integrated system with a compatible chip, comprising:
obtaining a layout design of a first functional chip and a layout design of the second functional chip;
determining a number n of pads of the first functional chip, a number p of pads of the second functional chip, and a number k of pads that need to be electrically connected between the first functional chip and the second functional chip according to the layout design of the first functional chip and the layout design of the second functional chip;
expanding the layout design of the first functional chip, designing a chip connection area outside the first functional chip, arranging p first pads on the chip connection area, arranging m second pads around the first functional chip and the p first pads, providing the first functional chip with n pads, electrically connecting the n pads of the first functional chip with n of the second pads in a one-to-one correspondence, and electrically connecting the p first pads with p of the second pads in a one-to-one correspondence to obtain a layout design of a first chip;
manufacturing the first chip with reference to the layout design of the first chip;
manufacturing the second functional chip with reference to the layout design of the second functional chip, and electrically drawing out the p pads from a front surface of the second functional chip; and
arranging the second functional chip on the chip connection area of the first chip through a one-to-one correspondence connection between the p pads of the second functional chip and the p first pads, and electrically connecting the k pads of the first functional chip with the k pads of the second functional chip in a one-to-one correspondence; wherein
m, n, p, k are integers greater than or equal to 2, and n<m<n+p, p<m<n+p, k<n, k<p, m=n+p−k.

10. The manufacturing method of the three-dimensional integrated system with the compatible chip according to claim 9, wherein
the first chip is provided with a first front surface and a first back surface arranged oppositely, the first functional chip, the p first pads and the m second pads are formed on the first front surface of the first chip, and the manufacturing method further comprises:
thinning the first back surface of the first chip;
etching the first back surface of the first chip, forming m through holes on the first back surface of the first chip, and the m through holes exposing the m second pads in a one-to-one correspondence; and
dicing, packaging and testing in sequence to obtain the three-dimensional integrated system.
